(19) United States
(12) Patent Application Publication
(10) Pub. No.: US 2011/0204231 A1
(43) Pub. Date: Aug. 25, 2011

(54) THERMAL DETECTION AND IMAGING OF ELECTROMAGNETIC RADIATION

(75) Inventors: Daniel Razansky, Munich, MA (US); Pinchas Einziger, Haifa (IL); Dan Adam, Haifa (IL); Yael Nemirovsky, Haifa (IL); Lior Shwartzman, Kiriat Haim (IL)

(73) Assignee: Technion Research & Development Foundation Ltd., Haifa (IL)

(21) Appl. No.: 11/817,745

(22) PCT Filed: Aug. 12, 2007
(86) PCT No.: PCT/IL2007/001004

§ 371 Date: May 3, 2011

Related U.S. Application Data
(60) Provisional application No. 60/836,700, filed on Aug. 10, 2006.

(51) Int. Cl. G01J 5/10; H01L 35/00

(52) U.S. Cl. 250/338.1; 257/467; 257/E29.347

(57) ABSTRACT

The current invention provides a method for improving the sensitivity of bolometric detection by providing improved electromagnetic power/energy absorption. In addition to its role in significantly improving the performance of conventional conducting-film bolometric detection elements, the method suggests application of plasmon resonance absorption for efficient thermal detection and imaging of far-field radiation using the Surface Plasmon Resonance (SPR) and the herein introduced Cavity Plasmone Resonance (CPR) phenomena. The latter offers detection characteristics, including good frequency sensitivity, intrinsic spatial (angular) selectivity without focusing lenses, wide tunability over both infrared and visible light domains, high responsivity and miniaturization capabilities. As compared to SPR, the CPR-type devices offer an increased flexibility over wide ranges of wavelengths, bandwidths, and device dimensions. Both CPR and SPR occur in metallic films, which are characterized by high thermal diffusivity essential for fast bolometric response.

### FIELD OF THE INVENTION

The present invention relates to novel micro-bolometer detection systems with high sensitivity for visible and infrared imaging.

### BACKGROUND OF THE INVENTION

Thermal bolometric detection and imaging have traditionally been based on absorption of infrared radiation by thin films of materials in their conducting, semiconducting or transition states. The heat, generated in the absorbing film, is then detected either by combining the functions of radiation absorption and thermometry within the film itself or by attaching some external thermometer element, as appropriate for composite bolometer designs. Both room temperature and cooled thermal detector arrays have found widespread applications. Thermal detection elements have been reported to be efficient and inexpensive when operating over a wide range of frequencies in the millimeter, submillimeter and infrared bands. Despite their low cost and other advantages, current thermal detection elements make use of relatively thick semiconducting absorbing films, which are usually characterized by non-optimal absorptive coupling and low thermal diffusivity. As a consequence, the devices have slow response times. For these reasons, most microbolometric elements are usually avoided in cases where well-developed photon detectors (e.g. CCD arrays) can be used, thus primarily exploited for detection of infrared and far-infrared spectrum. Bolometers are also efficient in the visible, ultraviolet and X-ray regions, but they have been avoided in cases where well-developed photon detectors can be used.

Plasmon detection has previously also been applied to imaging applications, such as evanescent wave two-dimensional imaging, near-field and far-field optical microscopy, and evanescent wave holography. Also, the thermal detection of surface plasmons was previously suggested, however, the application of plasmon resonance phenomena for thermal detection of far-field radiation, via microbolometer arrays, has not yet been proposed.

U.S. Pat. No. 6,344,272 entitled “Metal nanoshells” to Oldenburg, et al; Filed: Mar. 11, 1998 discloses particulate compositions and methods for producing them that can absorb or scatter electromagnetic radiation. The particles are homogeneous in size and are comprised of a nonconducting inner layer that is surrounded by an electrically conducting material. Introducing an optically absorbing species into the core will strongly influence the plasmon resonance shift and width.

These nanoparticles could be used to sensitize existing photovoltaic, photoconductive, or bolometric cells.

### REFERENCES

1. P. W. Kruse, D. D. Skatrud, editors, Uncooled infrared imaging arrays and systems, (San Diego; Tokyo: Academic Press, 1997).
2. P. L. Richards, “Bolometers for infrared and millimeter waves,” J. Appl. Phys. 76, 1 (1994).
3. L. A. L. de Almeida, G. S. Deep, A. M. N. Lima, I. A. Khrebtov, V. G. Malyarov, and H. Neff, “Modeling and performance of vanadium-oxide transition edge microbolometers,” Appl. Phys. Lett. 85, 3605 (2004).
4. N. S. Nishioka, P. L. Richards, and D. P. Woody, “Composite bolometers for submillimeter waves,” Appl. Opt. 17, 1562 (1978).
5. J. A. Shaw, P. W. Nugent, N. J. Pust, B. Thurairajah, and K. Mizutani, “Radiometric cloud imaging with an uncooled microbolometer thermal infrared camera,” Opt. Express 13, 5807 (2005).
6. S. H. Moseley, J. C. Mather, and D. McCammon, “Thermal detectors as x-ray spectrometers,” J. Appl. Phys. 56, 1257 (1984).
7. K. K. Choi, K. M. Leung, T. Tamir, and C. Monroe, “Light coupling characteristics of corrugated quantum-well infrared photodetectors,” IEEE J. Quantum Electron., 40, 130 (2004).
8. K. K. Choi, C. Monroy, A. Goldberg, G. Dang, M. Jhabvala, A. La, T. Tamir, K. M. Leung, A. Majumdar, J. J. Li, and D. C. Tsui, “Designs and applications of corrugated QWIPs,” Infr. Phys. Technol. 47, 76 (2005).
9. E. A. Smith and R. M. Corn, “Surface plasmon resonance imaging as a tool to monitor biomolecular interactions in an array based format,” Appl. Spectrosc. 57, 320A (2003).
10. M. Specht, J. D. Pedarnig, W. M. Heckl, and T. W. Hansch, “Scanning plasmon near-field microscope,” Phys. Rev. Lett. 68, 476 (1992).
11. D. O. S. Melville and R. J. Blaikie, “Super-resolution imaging through a planar silver layer,” Opt. Express 13, 2127 (2005).
12. I. I. Smolyaninov, J. Elliott, A. V. Zayats, and C. C. Davis, “Far-field optical microscopy with a nanometer-scale resolution based on the in-plane image magnification by the surface plasmon polaritons,” Phys. Rev. Lett. 94, 057401 (2005).
13. S. Maruo, O. Nakamura, and S. Kawata, “Evanescent-wave holography by use of surface-plasmon resonance,” Appl. Opt. 36, 2343 (1997).
14. R. A. Innes and J. R. Sambles, “Simple thermal detection of surface plasmon-polaritons,” Solid State Communications 55, 493 (1985).
15. S. I. Bozhevolnyi, T. Nikolajsen, and K. Leosson, “Integrated power monitor for long-range surface plasmon polaritons,” Opt. Communications 255, 51 (2005).
16. B. Carli and D. Iorio-Fili, “Absorption of composite bolometers,” J. Opt. Soc. Am. 71 (1981).
17. M. Born and E. Wolf, Principles of Optics: Electromagnetic Theory of Propagation, Interference and Diffraction of Light, 7th ed., (Cambridge University Press, Cambridge, 1999).
18. D. Razansky, P. D. Einziger, and D. R. Adam, “Broadband absorption spectroscopy via excitation of lossy resonance modes in thin films,” Phys. Rev. Lett. 95, 018101 (2005).
19. P. D. Einziger, L. M. Livshitz, J. Mizrahi, “Rigorous image-series expansions of quasi-static Green's functions for regions with planar stratification,” IEEE Trans. Antennas Propag. 50, 1813 (2002).
20. D. Razansky, P. D. Einziger, and D. R. Adam, “Optimal dispersion, relations for enhanced electromagnetic power deposition in dissipative slabs,” Phys. Rev. Lett. 93, 083902 (2004).
21. M. J. Weber, editor, Handbook of Optical Materials, (CRC Press, Boca Raton, 2003).

### SUMMARY OF THE INVENTION

One aspect of the invention is to provide a method of designing an optimized plane-stratified microbolometric element devices with higher sensitivity in thermal detection of ultraviolet, visible, infrared radiation, and short wavelength electromagnetic radiation such as sub-millimeter and millimeter waves.

Another aspect of the current invention is to provide a plane-stratified microbolometric element device utilizing plasmon resonance phenomena, such as Surface Plasmon Resonance (SPR) and herein proposed Cavity Plasmon Resonance (CPR), for achieving high performance. Improved performances may include good frequency sensitivity, intrinsic spatial (angle) selectivity without focusing lenses, wide tunability over both infrared and visible light domains, high responsivity and miniaturization capabilities. Both CPR and SPR occur in metallic films, which are characterized by high thermal diffusivity essential for fast bolometric response.

Another aspect of the invention is to provide a method of designing a plane-stratified microbolometric element device utilizing plasmon resonance phenomenon. The present invention provides a design method for optimization of bolometric detection using metallic and other conducting films. It also suggests exploiting the effect of plasmon resonance absorption of electromagnetic radiation in metallic films for highly efficient thermal (bolometric) detection of far-field radiation in various spectra, from ultraviolet and visible to near and far infrared and short wave electromagnetic radiation such as millimeter and sub-millimeter waves.

Another aspect of the invention is to provide a stratified microbolometric element device utilizing conducting (non-metallic) bolometric materials such as thin films of vanadium dioxide (VO₂) in its semimetal state, bismuth (Bi), carbon (C), and tellurium (Te). Alternatively, metals such as silver, gold, aluminum, and copper may be used. In contrast to microbolometric elements of the art, the stratified microbolometric element device according to the aspect of the invention achieves higher power absorption efficiency within said thin films. In some embodiments cooling requirements are minimized or eliminated due to the high sensitivity of the microbolometer element having high energy/power absorption.

Yet another aspect of the invention is to provide an observation system utilizing microbolometer element according to embodiments of the invention. In some embodiments, the high detection efficiency of the stratified microbolometric element is utilized. In some embodiments, the fast response of the stratified microbolometric element is utilized. In some embodiments, the narrow wavelength response of the stratified microbolometric element is utilized. In some embodiments, the narrow directional response of the stratified microbolometric element is utilized. In some embodiments an array of stratified microbolometric elements is utilized.

In this invention, we explore optimal absorption by plane-stratified bolometric elements and outline an approach for the characterization of optimal materials and structures that may provide total absorption of the incident electromagnetic radiation. Particularly, we propose to utilize plasmon resonance phenomenon for design of highly efficient detection element incorporating thin noble metal films. Surface plasmon detection has previously been applied to various imaging applications, such as evanescent wave two-dimensional imaging (reference [5]), near-field (reference [6]) and far-field optical microscopy (reference [7]). However, the application of plasmon resonance for thermal detection and imaging of far-field radiation has not yet been proposed. We also describe, for the first time, the phenomenon of Cavity Plasmon Resonance (CPR) that, like the well-known Surface Plasmon Resonance (SPR), occurs in metallic films.

Another aspect of this invention suggests using the resonant nature of the CPR phenomenon in order to replace the currently wide-spread Surface Plasmon Resonance (SPR) spectroscopy/biosensing techniques. SPR spectroscopy has demonstrated unprecedented performance in label-free real-time probing of various biopolymer, ligand, protein, and DNA interactions. Since its inception in the late sixties, the basic physical phenomenon underlying the SPR biosensing remained unchanged, namely, resonant absorption of TM-polarized light incident upon a metallic nanofilm above the critical total internal reflection angle. Since the SPR field is strictly confined to the metal-analyte interface, the measurements are usually limited to molecular adsorbates located in an immediate vicinity of this surface.

In contrast to the classical SPR, that requires very specific excitation conditions, which could be disadvantageous in some practical designs, the CPR does not require complicated evanescent field excitation conditions above the critical total internal reflection angle and may be implemented for both transverse electric (TE) and transverse magnetic (TM) fields even under normal incidence (TEM). These and other unique features of CPR enable a more flexible design of not only highly efficient thermal detector (bolometric) elements but also a new highly sensitive and flexible biosensing and spectroscopic devices.

According to the invention, a stratified bolometric detector is provided comprising: a substrate;

an absorbing film for absorbing incoming radiation by excitation of plasmon in said absorbing film, and converting said absorbed radiation to heat, wherein plasmon resonance absorption of said radiation increases the fraction of radiation absorption by at least ten percents; and electrical circuit for detecting electrical signal indicative of temperature increase caused by said heat.

In some embodiment gap between the absorbing film and the substrate comprises a resonance cavity.

In some embodiment the stratified bolometric detector further comprises a reflector deposited on front surface of the substrate.

In some embodiment the stratified bolometric detector further comprises a substantially transparent prism attached to the front surface of the absorbing film.

In some embodiment the plasmon resonance absorption increases the fraction of radiation absorption to at least ninety percents.

In some embodiment the plasmon resonance absorption increase is over a narrow range of wavelengths.

In some embodiment the plasmon resonance absorption increase is over a narrow angular range of the incoming radiation.

In some embodiment the absorbing film comprises material selected from the group of: vanadium dioxide, bismuth, carbon, and tellurium.

According to the invention, a method for detecting electromagnetic radiation is provided comprising the following steps: resonantly exciting plasmons in an absorbing film by absorbing electromagnetic radiation; increasing temperature of said absorbing film by said absorbed radiation; and detecting signal indicative of said temperature increase.

In some embodiment the step of detecting signal indicative of the said temperature increase comprises detecting the change in electrical resistance of thermo-sensitive material attached to the radiation absorbing film.

In some embodiment the step of detecting signal indicative of the said temperature increase comprises detection change of electrical resistance of the radiation absorbing film itself.

According to the invention, an observation system for observing electromagnetic radiation is provided comprising: at least one stratified bolometric detector comprising: a substrate; an absorbing film for absorbing incoming radiation by excitation of plasmon in said absorbing film, and converting said absorbed radiation to heat, wherein plasmon resonance absorption of said radiation increases the fraction of radiation absorption by at least ten percents; and electrical circuit for detecting electrical signal indicative of temperature increase caused by said heat; and a data acquisition unit receiving signals from said at least one stratified bolometric detector, wherein response of said at least one stratified bolometric detector is intrinsically limited to at least one of: limited range of wavelengths and limited range of incoming radiation direction.

In some embodiment the observation system further comprising an array of stratified bolometric detector.

In some embodiment the array of stratified bolometric detector comprises of substantially unequal bolometric detectors.

In some embodiment the observation system provides spectral information on incoming radiation wherein the substantially unequal bolometric detectors are responsive to different narrow wavelength ranges.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. In case of conflict, the patent specification, including definitions, will control. In addition, the materials, methods, and examples are illustrative only and not intended to be limiting.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1(a) schematically depicts an isometric view of a microbolometer element detector according to an embodiment of the current invention.

FIG. 1(b) schematically depicts a side view of a bolometric detector with integrated electronics according to an embodiment of the current invention.

FIG. 1(c) schematically depicts a top view of 2D bolometric detector array according to an embodiment of the current invention.

FIG. 2(a) schematically depicts the general four-layer model of a microbolometer element detector according to an embodiment of the current invention.

FIG. 2(b) schematically depicts a cross section of a microbolometer element configured in Surface Plasmon Resonance (SPR) configuration according to an embodiment of the current invention and shows the field distribution within its layers.

FIG. 2(c) schematically depicts a cross section of a microbolometer element configured in Cavity Plasmon Resonance (CPR) configuration according to an embodiment of the current invention and shows the field distribution within its layers.

FIG. 3 schematically depicts the optimal absorption paths for various total absorption cases and intersection points, with some material dispersion curves.

FIG. 4(a) and (b) schematically depicts the power absorption efficiency in the vicinity of various lossy resonances

FIG. 4(a) schematically depicts the efficiency versus excitation wavelength.

FIG. 4(b) schematically depicts the efficiency versus angle of incidence.

FIG. 5 schematically depicts an observation system using a microbolometer according to an aspect of the current invention.

### DESCRIPTION OF THE PREFERRED EMBODIMENTS

The present invention relates to devices, methods and systems for highly efficient detection of ultraviolet, visible and infrared radiation using novel bolometric elements.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

In discussion of the various figures described herein below, like numbers refer to like parts. The drawings are generally not to scale. For clarity, non-essential elements were omitted from some of the drawings.

As used herein, an element or step recited in the singular and proceeded with the word “a” or “an” should be understood as not excluding plural elements or steps, unless such exclusion is explicitly recited.

### 1. Construction of a Microbolometer Element

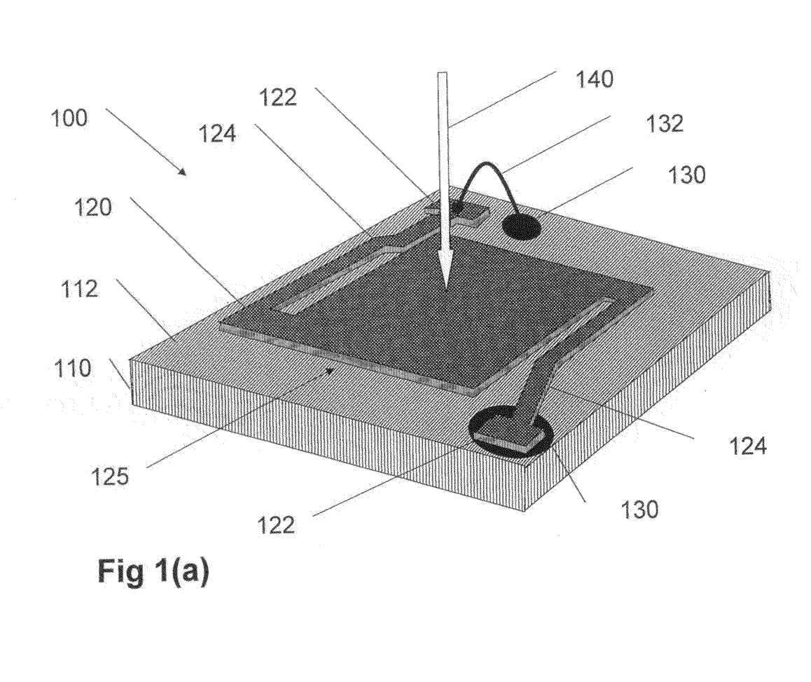

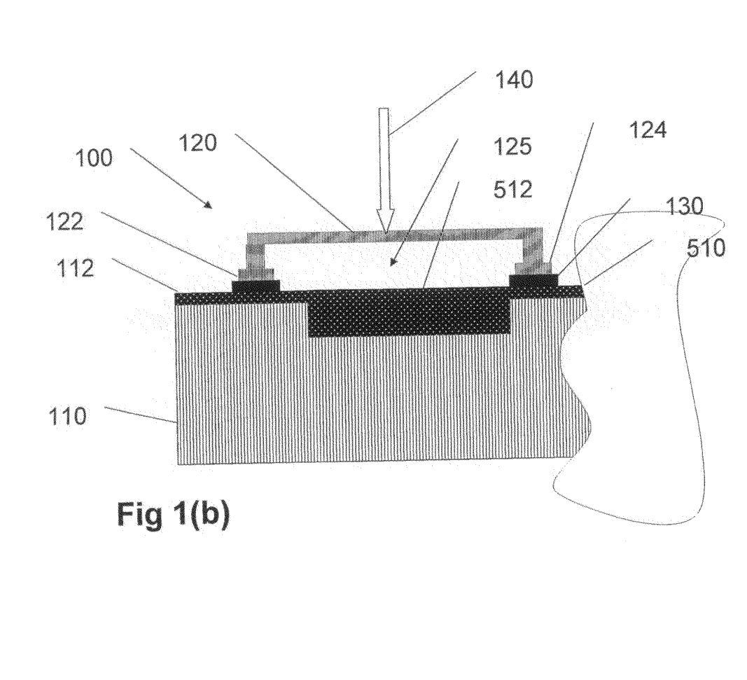

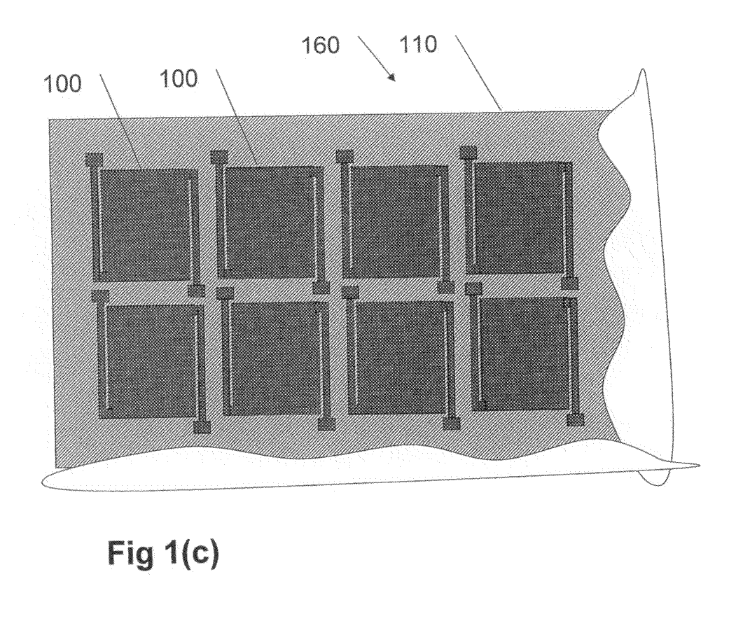

FIG. 1(a) schematically depicts an isometric view of a microbolometer element detector according to an embodiment of the current invention.

Microbolometer element 100 comprises a substrate 110 having a front surface 112. Absorbing film 120 is attached to front surface 112 at anchors 122.

Preferably, leads 124 are used for lifting or holding absorbing film 120 above the front surface 112 of substrate 110 creating a gap 125 therebetween. Optionally, leads 124 acts to reduce heat transfer between absorbing film 120 and substrate 110, thus increasing the sensor's sensitivity. Preferably leads 124 acts as electrical, connections for electrical signals indicative of temperature of absorbing film 120. For example, anchors 122 may be attached to electronic pads 130 on substrate 110. Alternatively, wire bond 132 is used for connecting anchors 122 to electronic pads 130. Alternatively or additionally, spacers (not shown in this figure) may be used for defining the distance between absorbing film 120 and front surface 112.

Substrate 110 preferably comprises of electrical conductors for transmitting electronic signals from detector 100 to signal conditioning circuits and data acquisition system. Optionally, substrate 110 comprises of semi-conductor material such as Silicon, Germanium or Gallium Arsenide. Optionally, active signal conditioning circuits are integrated into substrate 110. Alternatively, substrate 100 may be a passive substrate. Passive substrate may be made of insulating material such as glass, ceramics, plastic etc. Preferably, passive substrate includes conductive lines, preferably created using printed circuits technology.

Front surface 112 may be optically smoothed and act as a total or partial optical reflector. Optionally, an optical layer, such as metal reflector, dielectric anti-reflection coating; or dielectric mirror may be coated on top of front surface 112.

Incoming radiation 140 is impinges on, and at least partially absorbed by absorbing film 120 causing temperature increase of said absorbing film 120.

Microbolometer element 100 may be fabricated using microelectronics and micromachining techniques.

FIG. 1(b) schematically depicts a side view of a bolometric detector with integrated electronics according to an embodiment of the current invention.

Bolometric detector 100 comprises a substrate 110 having a front surface 112. Absorbing film 120 is attached to front surface 112 at anchors 122. Optionally, leads 124 are used for lifting absorbing film 120 above the front surface 112 of substrate 110 creating gap 125. Optionally, leads 124 acts to reduce heat transfer between absorbing film 120 and substrate 110, thus increasing the sensor's sensitivity. Preferably leads 124 acts as electrical connections for electrical signals indicative of temperature of absorbing film 120. For example, anchors 122 may be attached to electronic pads 130 on substrate 110.

Optionally, substrate 110 comprises of semi-conductor material such as Silicon, Germanium or Gallium Arsenide. Optionally, active signal conditioning circuits 512 are integrated into substrate 110. Substrate 110 preferably comprises of electrical conductors 510 for transmitting electronic signals from detector 100 to signal conditioning circuits 512.

Incoming radiation 140 is impinges on, and at least partially absorbed by absorbing film 120 causing temperature increase of said absorbing film 120.

FIG. 1(c) schematically depicts a top view of 2D bolometric detector array 160 according to an embodiment of the current invention.

Bolometric detector array 160 comprises substrate 110 and plurality of bolometric detector elements 100. In some embodiments bolometric detector elements 100 are substantially identical. In other embodiments, at least one of the detector elements has different construction. In some embodiments, each of the detector elements has unique construction. In other embodiments, elements in each row of elements are substantially identical.

Bolometric detector array 160 may be a two dimensional (2D) array as depicted in the FIG. 1(c). However, 1D array may be constructed. Other distributions of detector elements on the substrate, for example in form of concentric circles, arches, and even pseudo-random configuration are also possible.

It should be noted that dimensions of elements and their shape can vary.

### 2. Plane Stratified Model for Microbolometer Element

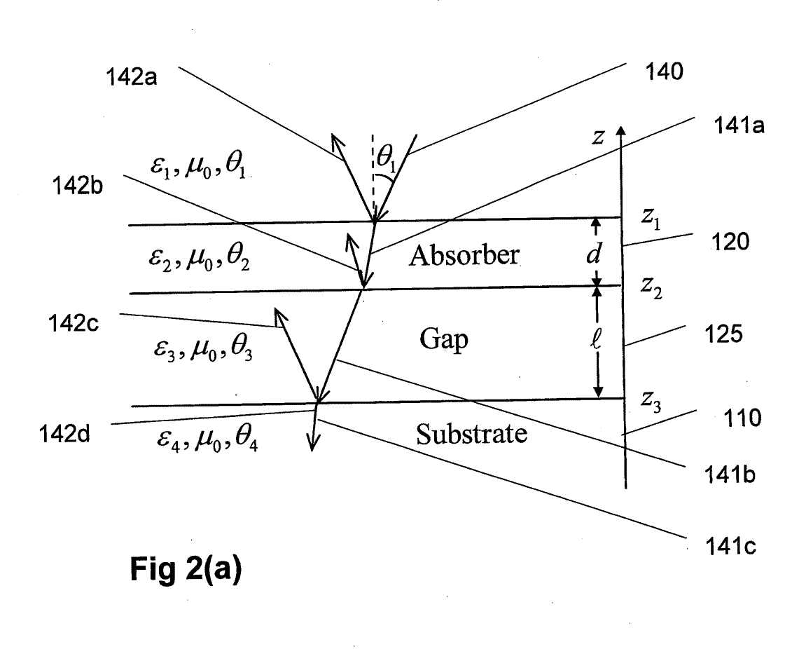

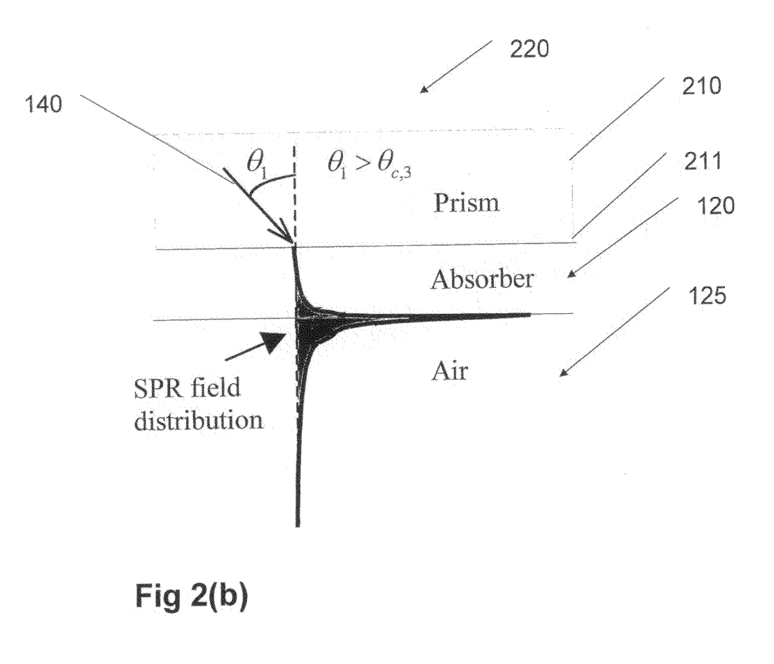

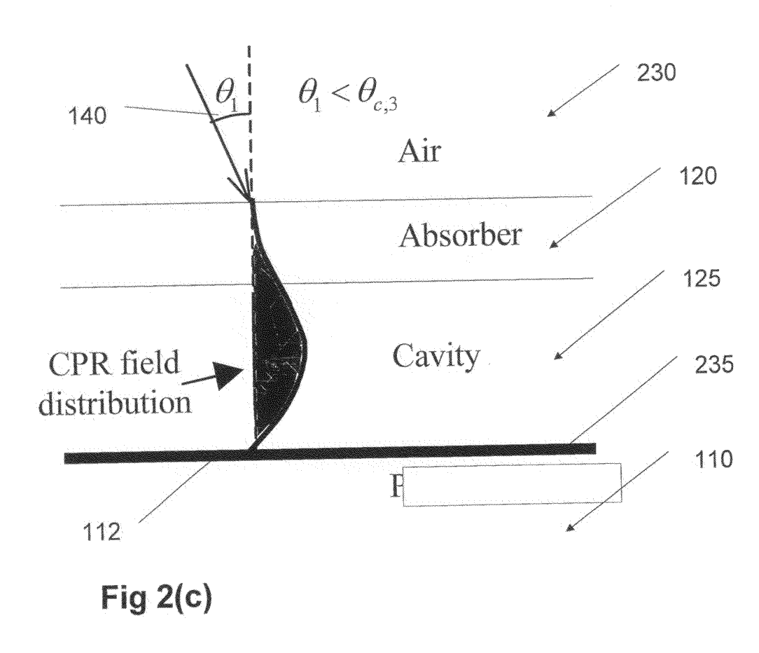

FIG. 2(a) schematically depicts the general four-layer model of a microbolometer element detector according to an embodiment of the current invention.

A radiation-absorbing microbolometer element typically consists of an absorbing film of thickness d located at a height l above a substrate layer, which may include, for example, some CMOS compatible read-out electronics. Preferably, the dimensions are optimized for maximizing radiation absorption in the frequency window of interest. Lossy resonance, i.e. full absorption of the incident wave by the absorbing film, is then considered to achieve optimal electromagnetic performance of the device. For fast operation, good responsivity and sensitivity, all the sensing elements preferably have low heat capacity and high thermal conductivity while either external or combined (composite) thermometric elements should be characterized by a high Temperature Coefficient of Resistance (TCR).

As shown in FIG. 2(a), the electromagnetic wave of incoming radiation 140 is incident at an angle θ₁ upon the absorbing film 120. For simplicity, we shall henceforth assume that all the media are lossless (∈_{q} are pure real, q=1, 3, 4) except for the absorbing film (∈₂ complex). As usual, the propagation angles or internal refracted beams 141a-141c in all the layers are determined via Snell's law, i.e. n₁ sin θ₁=n₂ sin θ₂=n₃ sin Σ₃=n₄ sin θ₄, where the refractive indexes are given via n_{q}=\sqrt{∈_{q}/∈₀} (q=1, 2, 3, 4). Subsequently, the critical incidence angles are given via θ_{c,q}=sin⁻¹)n_{q}/n₁). Reflected beams 142a-142d are assumed to be specular reflections of the input and refracted beam respectively. For clarity, second order beams were not marked in this drawing. The field solutions in such a multilayer refraction problem are generally known (e.g. reference [17]) and the power absorption efficiency of the absorbing film can be defined as

η=1−|R₁|²−|T₄|² [symbol] {N₄}, (1)

which is a direct extension of the formulation developed in reference [18] for the current four-layer configuration, written in terms of the global field reflection and transmission coefficients R₁ and T₄. The latter can be conveniently recovered through an iterative procedure (reference [19]) where, for the four layers of interest q=1, 2, 3, 4, one obtains

$$\begin{matrix}{R}_{q} = \frac{{r}_{q} + {R}_{q + 1} {e}^{- i 2 {k}_{0} {n}_{q + 1} {z}_{q} cos {θ}_{q + 1}}}{1 + {r}_{q} {R}_{q + 1} {e}^{- i 2 {k}_{0} {n}_{q + 1} {z}_{q} cos {θ}_{q + 1}}} {e}^{i 2 {k}_{0} {n}_{q} {z}_{q} cos {θ}_{q}} , {R}_{4} = 0 \\ and & ( 2 ) \\ {T}_{q} = {\prod }_{m = 2}^{q} \frac{( 1 + {r}_{m - 1} ) {e}^{i {k}_{0} ( {n}_{m - 1} cos {θ}_{m - 1} - {n}_{m} cos {θ}_{m} ) {z}_{m - 1}}}{1 + {r}_{m - 1} {R}_{m} {e}^{- i 2 {k}_{0} {n}_{m} {z}_{m - 1} cos {θ}_{m}}} , {T}_{1} = 1 & ( 3 )\end{matrix}$$

with k₀=ω\sqrt{∈₀μ₀} and the normalized refractive indexes N_{q}, local refraction coefficients r_{q}, and their associated phases ψ_{q} defined via

$${N}_{q}^{{TE}_{TM}} = \frac{{n}_{q}}{{n}_{1}} {( \frac{cos {θ}_{q}}{cos {θ}_{1}} )}^{\pm 1} , {r}_{q} = \frac{{N}_{q} - {N}_{q + 1}}{{N}_{q} + {N}_{q + 1}} = {( - 1 )}^{q} {e}^{l {ψ}_{q}} , {r}_{4} = 0. \qquad ( 4 )$$

The superscripts TE and TM have been retained in Eqs. (1)-(4) only in those terms that distinguish between the two elementary plane-wave polarizations. This rule is adopted throughout the paper for all subsequent relations. From (1) it can readily be noticed that full absorption (η=1) can be achieved if two conditions are satisfied, namely, (i) either T₄=0 or [symbol] {N₄}=0 and (ii) R₁=0. When T₄=0, i.e. r₃=−1 in (4), no energy penetrates into the substrate layer n₄ and an equivalent lossy resonance cavity appears in the region z₃≦z≦z₁=0 due to a perfect mirror at z=z₃ (FIG. 2(c)) and no reflection at z=z₁. Alternatively, the term [symbol] {N₄} vanishes when exciting evanescent plane waves in the region z≦z₃, which may lead to the classical Surface Plasmon Resonance (SPR) situation described in FIG. 2(b) upon setting n₃=n₄ (leading to z₃=z₂.

FIGS. 2(b) and 2(c) schematically depict two novel structures for a microbolometer according to the current invention.

FIG. 2(b) schematically depicts a cross section of a microbolometer element configured in Surface Plasmon Resonance (SPR) configuration 220 according to an embodiment of the current invention and shows the field distribution within its layers.

Input beam entering 140 at angle θ₁ respective to the surface of absorber film 120. In this configuration, gap 125 is large compared to the extant of the SPR field distribution. Since the field does not substantially interact with the substrate, the substrate is not seen in this figure. Optionally, reflection from the substrate is reduced, for example by having substrate with low reflection coefficient; coating the substrate with low reflection coating, coating the substrate with anti reflection coating which causes large percentage of the radiation to be absorbed by the substrate; or having a substrate which scatters the light, for example by having rough surface.

Optional substantially transparent material 210 affixed to front surface of absorptive film 211 and having index of refraction unequal to 1.0 (marked as “Prism” in the drawing) may be used for refractivity control the entrance angle θ₁ and affect the penetration of the radiation into the absorber film. Additionally, optional prism 210 may be used for supporting absorptive film 120, thus enabling the elimination of the substrate.

In an array of detectors, prism 210 may be an individual prism for each of the array elements. Optionally properties of prisms attached to different elements are not the same. Alternatively one prism may be attached to plurality or all the elements in the array. Prism 210 may be part of an optical system for manipulating the input beam. For example, prism 210 may have focusing or collimation properties for manipulating or limiting the range of input angles. Additionally or alternatively, prism 210 may have wavelength filtering properties for manipulating or limiting the range of wavelength of the input beam.

FIG. 2(c) schematically depicts a cross section of a microbolometer element configured in Cavity Plasmon Resonance (CPR) configuration 230 according to an embodiment of the current invention and shows the field distribution within its layers.

Input beam entering 140 at angle θ₁ respective to the surface of absorber film 120. In this configuration, gap 125 forms an optical resonance cavity between absorber film 120 and mirror 235 on front surface 112 of substrate 110.

Preferably, mirror 235 is a high reflectance mirror. For example a metallic or dielectric coating on front surface 112 of substrate 110 may form a substantially “perfect mirror” having close to 100% reflectance for the input wavelength.

As already noted, R₁ must also vanish in (1) to achieve total absorption. Utilizing (2), this term can be explicitly expressed as

$${R}_{1} = \frac{{r}_{1} + {ρ}_{2} {e}^{i2 {k}_{0} {dn}_{2} cos {θ}_{2}}}{1 + {r}_{1} {ρ}_{2} {e}^{i2 {k}_{0} {dn}_{2} cos {θ}_{2}}} , \qquad ( 5 )$$

where the composite local refraction coefficient ρ₂ is defined via

$${ρ}_{2} = \frac{{N}_{2} - \tilde{{N}_{3}}}{{N}_{2} + \tilde{{N}_{3}}} , \tilde{{N}_{3}} = i {N}_{3} cot ( γ + {ψ}_{3} / 2 ) , γ = {k}_{0} l {n}_{3} cos {θ}_{3} . \qquad ( 6 )$$

The composite normalized refractive index N~₃ actually incorporates the effects of two layers (n₃ and n₄), so that Eq. (5) expresses the well-known global reflectivity of a single slab (reference [17]), but with ρ₂ replacing r₂, i.e. N~₃ replacing N₃.

### 3. Full Absorption Cases

As mentioned above, the two full-absorption (η=1) cases of interest are given by either lossy resonance cavity (T₄=0 or total internal reflection ( [symbol] {N₄}=0. The latter is satisfied when θ₁ is above the critical angle, i.e. θ₁>θ_{c,4}, whereas the former is realized by placing a perfect mirror at z=z₃, leading to N₄=∞ and ψ₃=0.

Table 1 summarizes full absorption conditions, obtained for these two general cases. Evidently, they are both characterized by purely imaginary composite normalized refractive index, namely [symbol] {N~₃}=0, as expected for zero power transmission into the substrate layer (z<z₃). We shall now focus on conducting and metallic-type absorbers, corresponding to ℑ{N~₃}=0 and ℑ{N~₃}<0, respectively. For both perfect mirror (T₄=0) and total internal reflection (θ₁>θ_{c,4}=sin⁻¹(n₄/n₁)) cases, optimal absorption by metallic films can be implemented either below (CPR) or above (SPR) the critical angle θ_{c,3}=sin⁻¹(n₃/n₁). While the condition ℑ{N~₃}<0 is satisfied by all polarizations (TE/TM/TEM) in the CPR case, only the TM polarization is admissible for the SPR case. Note that the previously discussed SPR case for single slab configuration (reference [18]), for which N~₃=N₃, is recovered either by selecting identical materials in the third and fourth regions, i.e. n₃=n₄ (FIG. 2(b)), or by placing the mirror at a sufficiently large distance γ→∞ in FIG. 2(c).

TABLE 1
Full absorption (η = 1) conditions for configurations (a) with perfect
mirror termination (T₄ = 0) and (b) under total internal reflection (θ₁ > θ_{c,4}).

| | |
|---|---|
| Incidence angle and | Absorption regimes and associated conditions |
| polarizations | p = 0, 1, 2, . . . |

(a)

| | |
|---|---|
| 0 ≦ θ₁ < θ_{c,3} | Good conductor: ℑ{N^{~}₃} = 0, ℑ{cosθ₃} = 0, |
| TE/TM/TEM | ${r}_{3} = - 1 , γ = \frac{π}{2} + p π$ |
| | CPR: ℑ{N^{~}₃} < 0, ℑ{cosθ₃} = 0, |
| | ${r}_{3} = - 1 , \frac{π}{2} + p π < γ < π + p π$ |
| θ_{c,3} < θ₁ < π/2 | SPR: ℑ{N^{~}₃} < 0, [symbol] {cosθ₃} = 0, r₃ = −1 |
| TM only | |

(b)

| | |
|---|---|
| θ_{c,4} < θ₁ <θ_{c,3} | Good conductor: ℑ{N^{~}₃} = 0, ℑ{cosθ₃} = 0, |
| TE/TM/TEM | \|r₃\| = 1, γ + ψ₃/2 = π/2 + pπ |
| | CPR: ℑ{N^{~}₃} < 0, ℑ{cosθ₃} = 0, |
| | $\vert {r}_{3} \vert = 1 , \frac{π}{2} + p π < γ + {ψ}_{3} / 2 < π + p π$ |
| θ_{c},₃ < θ₁ < π/2 | SPR: ℑ{N^{~}₃} < 0, [symbol] {cosθ₃} = 0, 0 ≦ r₃ < 1 |
| TM only | |

To clarify the current analytical formulation, we obtain explicit asymptotic expressions for the optimal absorbing film material as a function of various parameters, i.e. film thickness d and its distance from the substrate l, angle of incidence θ₁, and excitation frequency ω. The asymptotic derivations are most conveniently facilitated by introducing the normalized film thickness δ as

δ_{TM}^{TE}=k₀n₁d cos^{±1}θ₁. (7)

Two asymptotic full absorption situations are of particular interest, namely, the case of a thin layer, i.e. δ<<1, and the case for which the absorbing film cannot be considered as thin, i.e. δ˜1. Following the procedures described in [18], while requiring R₁=0 in (5), one obtains asymptotic expressions for the optimal normalized refractive index of the absorbing film N_{2,opt} as

N_{2,opt}=(1+i)\sqrt{(1−N~₃)/(2δ)}, for δ<<1, (8)

and

N₂ₒₚₜ=−N~₃(1+2e^{-2iδN~}^{₃}^{-2/N~}^{₃}), for δ˜1. (9)

Since the focus here is on conducting or metallic-type absorbers, only the zero-order mode (m=0 in [18]) optimal asymptotic solution is given for the thin-film case in (8). Higher-order modes that provide appropriate optimal solutions supported by low loss (insulating) materials are not shown.

It should be noted that in order for the metal film to fully absorb the incident radiation it has to be inductively loaded (see Table 1, ℑ{N~₃}<0). This can be carried out by TM-mode only above the critical angle (SPR) and by both TE/TM/TEM below the critical angle (CPR). Furthermore, as can be verified from FIG. 2(b) and (c) and Eq. (9), the local reflection coefficient at the interface ∈₂-∈₃ becomes very large, i.e. approaching surface pole singularity for both CPR and SPR. Thus, the terms CPR and SPR here indicate perfect metallic absorbers operating in plasma frequencies rather than plasmon-polariton guiding devices.

### 4. Classification of the Optimal Absorbing Film Materials

When the thin film case (δ<<1) is applied to the typical CPR configuration depicted in FIG. 2(c), the optimally absorbing film material, represented by N_{2,opt} or n_{2,opt}, is dependent on its normalized distance γ from the perfect mirror. For pπ≅γ<π/2+pπ, p=0, 1, 2, . . . (i.e. ℑ{N~₃}>0), the loss angle of either N_{2,opt} or n_{2,opt} will be less than 45°, representing low-loss materials with [symbol] {n_{2,opt}}>>ℑ{n_{2,opt}}. When the mirror is placed at γ=π/2+pπ (i.e. ℑ{N~₃}=0), the loss angle of optimally absorbing materials in (8) coincides with the dispersion condition of good electric conductors, which corresponds to a loss angle of 45° (i.e., [symbol] {n_{2,opt}}=ℑ{n_{2,opt}}). Widely utilized bolometric materials, characterized by this dispersion, include thin films of vanadium dioxide (VO₂) in its semimetal state, bismuth (Bi), carbon (C), and tellurium (Te) (reference [2-4]). However, lossy resonance excitation of materials in their conducting state with γ=π/2+pπ is usually not possible for infrared wavelengths and below. The reason is that, as wavelength decreases, the dispersion of good conductors changes its behavior either into metallic-plasma-like or anomalous absorption states whose loss angle deviates from the optimal value of 45°, thus making the optimal (η=1) excitation impossible. On the other hand, lossy resonance excitation is indeed possible also at much lower wavelengths by using metals in their near-plasma band. One notes from (8) that for the thin film limit, if π/2+pπ<γ<(p+1)π (i.e. ℑ{N~₃}<0), the optimally absorbing film is actually of a plasma type since its loss angle is then above 45°. Moreover, when the film becomes relatively thick (δ˜1), the asymptotic optimal solutions in (9) are inherently of the plasmon resonance type. Their dispersion is that of metals in their plasma band with loss angle between 45° and 90°. Obviously, the CPR optimal absorption holds equally well for both TE and TM polarizations below the critical angle (i.e. for θ₁<θ_{c,3}), including normal TEM incidence. Without the mirror, however, full absorption can be obtained only for the well-known TM polarization SPR situation described in FIG. 2(b), which involves incidence above the critical angle (i.e. for θ₁>θ_{c,3}).

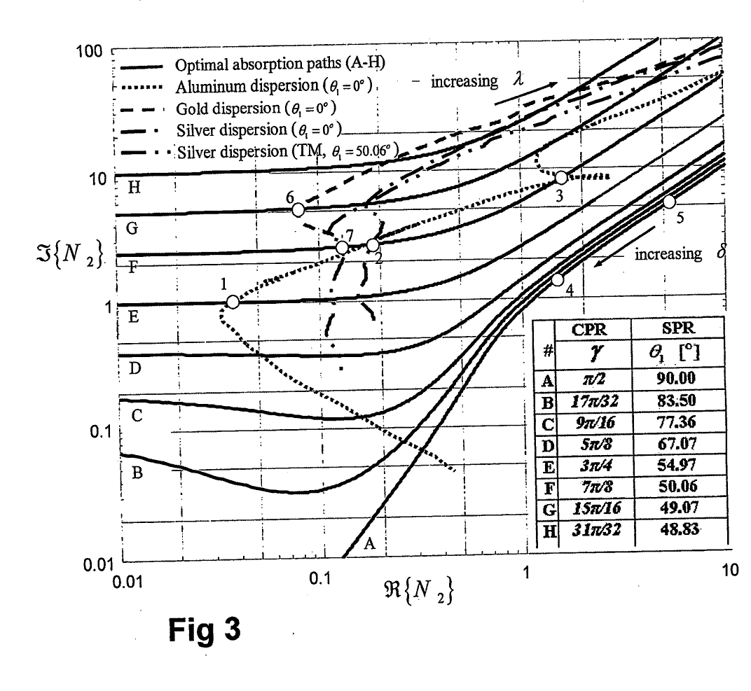

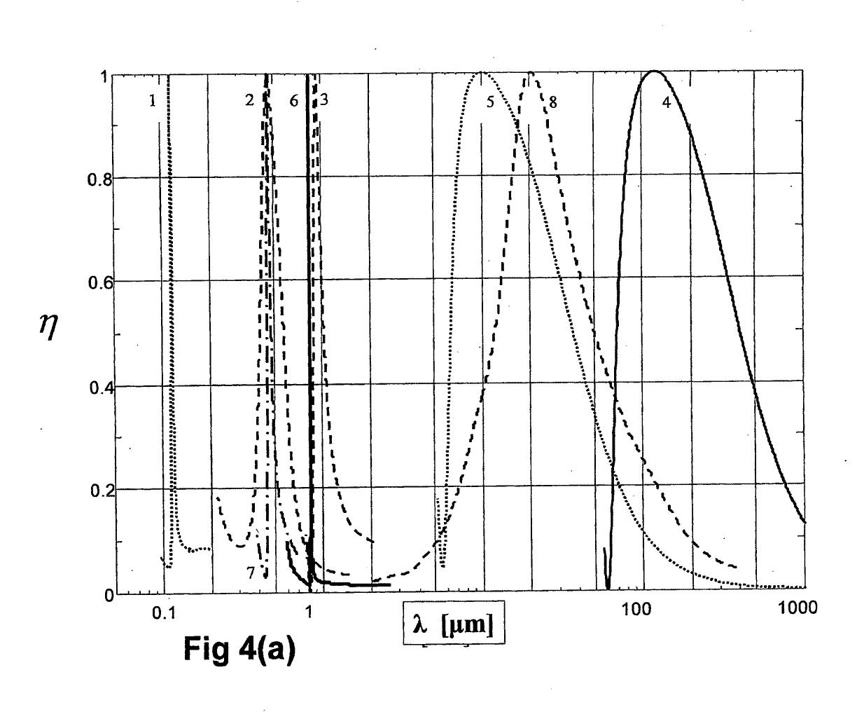

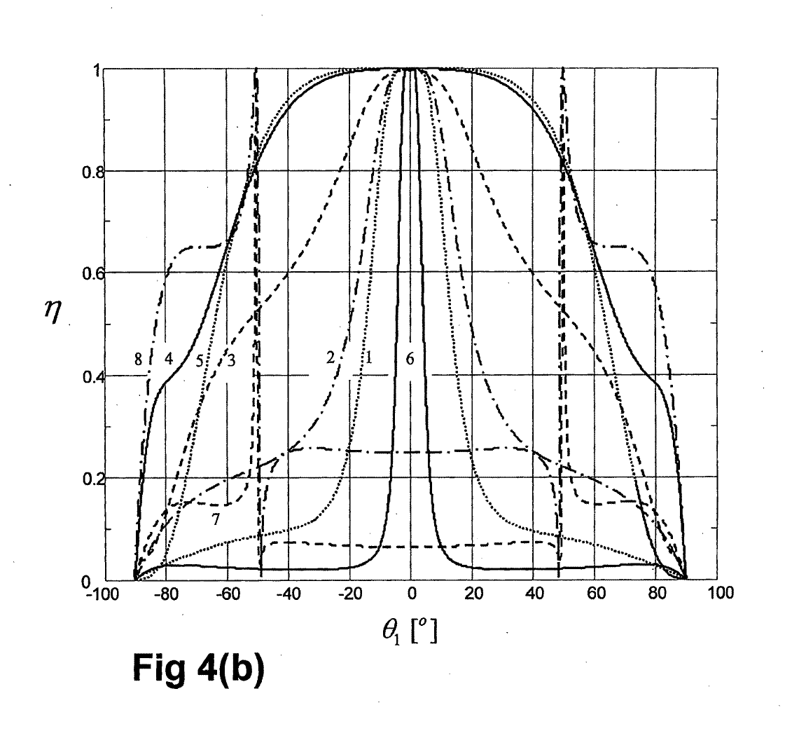

The above conclusions are further demonstrated via FIG. 3 where the exact solutions of R₁=0 for either CPR (FIG. 2(c)), setting θ₁=0) or SPR (FIG. 2(b)) are represented via optimal absorption paths [18, 20] in the normalized complex dispersion N₂ domain. Along each path the value of δ varies continuously whereas the power absorption efficiency η in (1) is exactly 100% for constant γ and θ₁. It should be noted that the same path is obtained for either CPR or SPR, by properly setting γ and θ₁ so as to obtain identical N~₃ in (6) and (9). Also, normalized dispersions of some metals and conductors (Table 2) are depicted in FIG. 4 (dashed lines) versus the excitation frequency.

TABLE 2
Configuration parameters for intersection and full absorption
points, as depicted in FIGS. 3 and 4, respectively.

| Case # | 1 | 2 | 3 | 4 | 5 | 6 | 7 | 8 |
|---|---|---|---|---|---|---|---|---|
| Absorption Mode | CPR | CPR | CPR | Good | Good | CPR | SPR | SPR |
| | | | | conductor | conductor | | | |
| Film material | Al | Ag | Al | VO₂ | C | Au | Ag | Ag |
| θ_{c, 4} [°] | — | — | — | — | — | — | 48.754 | 48.754 |
| θ₁ [°] | 0 | 0 | 0 | 0 | 0 | 0 | 50.06 | 50.06 |
| l [μm] | 0.043 | 0.202 | 0.409 | 2.604 | 29.76 | 0.389 | ∞ | ∞ |
| dₒₚₜ [nm] | 36.44 | 31.94 | 5.47 | 331.56 | 378.93 | 47.04 | 33.6 | 1.1 |
| λₒₚₜ [μm] | 0.114 | 0.463 | 0.928 | 118.85 | 9.98 | 0.833 | 0.785 | 27.5 |
| Normalized | 2.01 | 0.43 | 0.037 | 0.018 | 0.24 | 0.35 | 0.57 | 0.0005 |
| thickness - δₒₚₜ | | | | | | | | |

The intersection points between the optimal absorption paths and material dispersion curves of the specific material used represent the full absorption or lossy resonance conditions and provide the required optimal design values, i.e. film thickness dₒₚₜ and excitation frequency ωₒₚₜ, per given substrate distance l and incidence angle θ₁. The dispersions of materials in their good conducting state coincide with the γ=π/2+pπ optimal absorption path in the N₂ domain (FIG. 3, curve A), creating overlapping regions instead of intersection points with more broadband optimal absorption [20] as compared to that of both CPR and SPR.

The sensitivity of the power absorption efficiency in the vicinity of different lossy resonance conditions (intersections and overlapping regions from FIG. 3) as a function of excitation frequency and incidence angle are shown in FIG. 4, subject to the precise configuration parameters given in Table 2. The specific examples include broadband absorption by good conducting carbon and vanadium dioxide films in the submillimeter and infrared bands, narrowband absorption by CPR and SPR excited silver film in the visible band, and excitation of gold and aluminum films in near-infrared and ultraviolet bands.

FIG. 3 schematically depicts the optimal absorption paths (solid lines, A to H) for various total absorption cases and intersection points (1 to 7) with some material dispersion curves (dashed-dotted lines) in the complex N₂ domain. For the CPR configuration T₄=0, θ₁=0, and n₃=n₁ while for the SPR configuration [symbol] {N₄}=0, n₄=n₃, n₄/n₁=0.752 and θ₁>θ_{c,4}=sin⁻¹(n₄/n₁)=48.754°.

Configuration parameters for the intersection points appear in Table 2 (note that intersection number 8 in Table 2 is out of range here).

FIG. 4 schematically depicts the power absorption efficiency in the vicinity of various lossy resonances (configuration details are given in Table 2 and material dispersions are taken from references [1, 4, 21].

FIG. 4(a) schematically depicts the efficiency η versus excitation wavelength λ=c/f.

FIG. 4(b) schematically depicts the efficiency η versus angle of incidence θ₁.

The curve numbers here correspond to the full absorption (intersection) points as appear in FIG. 3 and Table 2 (note that intersection number 8 is out of range in FIG. 3).

Evidently, the CPR and SPR absorption is inherently characterized by high frequency and spatial selectivity, as depicted in FIGS. 4(a) and 4(b) respectively.

This high selectivity may be used for noise and jamming immunity and lenseless far-field imaging.

Furthermore, ultrathin absorbing films made of noble metals have intrinsically higher thermal diffusivity as compared to semiconductors and semimetals. Thus the corresponding bolometers feature a faster time response. Obviously, the cases shown in FIGS. 4(a,b) are not the only possible examples and, as suggested by FIG. 3, many other intersection points and overlapping regions exist, thus offering more flexibility for achieving full absorption in thin films over wide range of wavelengths, bandwidths, and device dimensions.

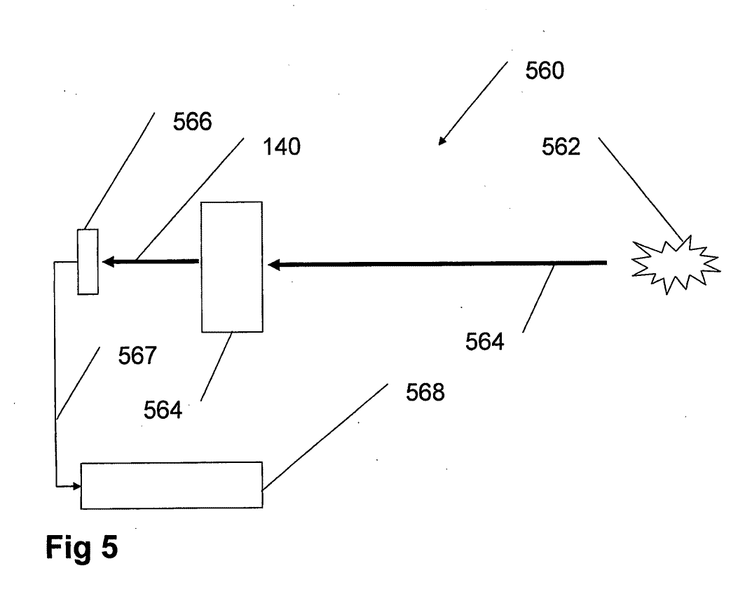

FIG. 5 schematically depicts an observation system 560 using a microbolometer 566 according to an aspect of the current invention.

Observation system 560 receives a signal beam 564 emitted by radiation source 562 to be observed.

Optionally, signal beam 564 traverses optical system 564 forming input radiation 140 which is detected by microbolometer detector 566. Signal 567 indicative of input radiation 140 is analyzed by data acquisition unit 568.

Optionally, optical system 564 may comprise one or few of: wavelength filter, for example absorptive or interference filter for rejecting at least some of the radiation; spatial filter for rejecting at least some of the incoming radiation angles based on directionality; focusing or imaging assembly such as a lens, combination of lenses, curved mirror/s or combinations of lenses and mirrors; wavelength dispersion device such as prism, grating or interferometer.

Additionally or alternatively, optical system 564 may comprise a time domain function such as: a chopper for affecting its transmittance; directional scanner; wavelength scanning device; or combination thereof. Alternatively, optical system 564 may be missing.

The absorption optimization method disclosed above may be applied for improving the sensitivity of planar microbolometric detection array elements. The optimally absorbing detection films can be implemented by either conducting, semi-conducting or plasmon-type (metallic) materials. It was further demonstrated that the novel application of plasmon resonance absorption for far-field thermal imaging offers improved characteristics for efficient far-field thermal detection and imaging, including high responsivity, miniaturization, and intrinsic spatial (angle) selectivity without focusing lenses.

Apart from the well-known surface plasmon resonance regime, the cavity plasmon resonance excitation of thin metallic films is introduced here for the first time. In the context of bolometric detection, the latter phenomenon may offer more flexibility over wide ranges of device dimensions as well as tunability over both infrared and visible light domains, high responsivity and miniaturization capabilities. Surface Plasmon Resonance (SPR) and Cavity Plasmon Resonance (CPR), offers more flexibility over wide ranges of wavelengths, bandwidths, and device dimensions. Both CPR and SPR occur in metallic films, which are characterized by high thermal diffusivity essential for fast bolometric response.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub combination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. A stratified bolometric detector comprising:
a substrate;
an absorbing film for absorbing incoming radiation by excitation of plasmon in said absorbing film, and converting said absorbed radiation to heat, wherein plasmon resonance absorption of said radiation increases the fraction of radiation absorption by at least ten percents; and
electrical circuit for detecting electrical signal indicative of temperature increase caused by said heat.

2. The stratified bolometric detector of claim 1 wherein gap between the absorbing film and the substrate as a resonance cavity.

3. The stratified bolometric detector of claim 2 and further comprising a reflector deposited on front surface of the substrate.

4. The stratified bolometric detector of claim 1 and further comprising a substantially transparent prism attached to the front surface of the absorbing film.

5. The stratified bolometric detector of claim 1 wherein plasmon resonance absorption increases the fraction of radiation absorption to at least ninety percents.

6. The stratified bolometric detector of claim 5 wherein plasmon resonance absorption increase is over a narrow range of wavelength.

7. The stratified bolometric detector of claim 5 wherein plasmon resonance absorption increase is over a narrow range incoming beam angulations.

8. The stratified bolometric detector of claim 1 wherein absorbing film comprises material selected from the group of: vanadium dioxide, bismuth, carbon, and tellurium.

9. The stratified bolometric detector of claim 1 wherein absorbing film comprises material selected from the group of: silver; gold; aluminum; and copper.

10. A method for detecting electromagnetic radiation comprising the step of:
resonantly exciting plasmons in an absorbing film by absorbing electromagnetic radiation;
increasing temperature of said absorbing film by said absorbed radiation; and
detecting signal indicative of said temperature increase.

11. The method for detecting electromagnetic radiation of claim 10 wherein the step of detecting signal indicative of temperature increase comprises detection change of electrical resistance caused by said temperature increase.

12. The method for detecting electromagnetic radiation of claim 11 wherein the step of detecting signal indicative of temperature increase comprises detection change of electrical resistance of the absorbing film caused by said temperature increase.

13. An observation system for observing electromagnetic radiation comprising:
at least one stratified bolometric detector comprising:
a substrate;
an absorbing film for absorbing incoming radiation by excitation of plasmon in said absorbing film, and converting said absorbed radiation to heat, wherein plasmon resonance absorption of said radiation increases the fraction of radiation absorption by at least ten percents; and
electrical circuit for detecting electrical signal indicative of temperature increase caused by said heat; and
data acquisition unit receiving signals from said at least one stratified bolometric detector, wherein response of said at least one stratified bolometric detector is intrinsically limited to at least one of:
limited range of wavelengths and limited range of incoming radiation direction.

14. The observation system of claim 13 and further comprising an array of stratified bolometric detector.

15. The observation system of claim 14 wherein array of stratified bolometric detector comprises of substantially unequal bolometric detectors.

16. The observation system of claim 16 for providing spectral information on incoming radiation wherein the substantially unequal bolometric detectors are responsive to different narrow wavelength ranges.

17. The observation system of claim 16 for providing imaging information on incoming radiation wherein the substantially unequal bolometric detectors are responsive to different narrow angular ranges.
